(19) United States
(12) Patent Application Publication
(10) Pub. No.: US 2018/0355199 A1
(43) Pub. Date: Dec. 13, 2018

(54) Photosensitive Material Sets

(71) Applicant: Hewlett-Packard Development Company, L.P., Houston, TX (US)

(72) Inventor: James Wiliam STASIAK, Corvallis, OR (US)

(73) Assignee: Hewlett-Packard Development Company, L.P., Houston, TX (US)

(21) Appl. No.: 16/060,094

(22) PCT Filed: Apr. 5, 2016
(86) PCT No.: PCT/US2016/025975

§ 371 Date: Jun. 7, 2018

(51) Int. Cl. C09D 11/322; C09D 11/38; C09D 11/54; B29C 64/165; G03F 7/004

(52) U.S. Cl. CPC C09D 11/322; C09D 11/38; B33Y 70/00; B29C 64/165; G03F 7/004; C09D 11/54

(57) ABSTRACT

A photosensitive material set can include a build material with polymeric particles having art average the from 10 μm to 100 μm and an average aspect ratio of less than 2:1, an inkjettable fluid suitable for application to the polymeric particles for 3D printing, and a photosensitive dopant. The photosensitive dopant can be blended with the polymeric particles, included in the inkjettable fluid, or both. The photosensitive dopant can have a first electrical property in a first chemical configuration and a second electrical property when modified to a second chemical configuration by exposure to photo electromagnetic radiation that is suitable to convert the photosensitive dopant from the first chemical configuration to the second chemical configuration.

### BACKGROUND

Methods of 3-dimensional (3D) digital printing, a type of additive manufacturing, have continued to be developed over the test few decades. However, systems for 3D printing have historically been vary expensive, though those expenses have been coming down to more affordable levels recently. In general, 3D printing technology improves the product development cycle by allowing rapid creation of prototype models for reviewing and testing. Unfortunately, the concept has been somewhat limited with respect to commercial production capabilities because the range of materials used in 3D printing is likewise limited. Nevertheless, several commercial sectors have benefitted from the ability to rapidly prototype end customize parts for customers. Various methods for 3D printing have been developed, including heat-assisted extrusion, selective laser sintering (SLS), fused deposition modeling (FDM), photolithography, as well as others. Accordingly, development of new 3D printing technologies continues, including in the area of functionalizing 3D printed objects.

### BRIEF DESCRIPTION OF THE DRAWINGS

FIG. 1 is a schematic representation of inkjettable fluids, photosensitive dopants, and polymeric particle build materials used for forming 3D objects or parts in accordance with examples of the present disclosure;

FIG. 2 is a schematic representation of inkjet ink, photosensitive dopants, and polymeric particle build materials used for forming 3D objects or parts in accordance with examples of the present disclosure; and

FIG. 3 is a schematic representation photosensitive dopant and polymer particle build material used for forming 3D objects or parts in accordance with examples of the present disclosure.

### DETAILED DESCRIPTION

The present disclosure relates to powder bed three dimensional printing processes where 3D parts can be made with select portions modified to enhance electrical properties or reduce electrical properties. In certain examples, this modification can occur at the three-dimensional voxel scale (i.e. at specific small pixel-like locations found in three-dimensional space or three-dimensional unit volume). Essentially, a build material which can be a particulate or powder fusable polymer, can be spread out layer by layer in a configuration to receive an ink or multiple inks, such as an inkjettable fluid or a fusible ink or combination thereof. The ink(s) and/or the build powder can include a photosensitive dopant (which can be a charge transport molecule). Prior to inking the powder layer (if the dopant is in the powder) or after inking the powder layer with photosensitive dopant a frequency of electromagnetic radiation can be applied thereto, such as with a laser or other energy source. There, the photosensitive dopant undergoes irreversible molecular reconfiguration. In one example, the irreversible molecular reconfiguration can cause the photosensitive dopant to enhance or turn on the electrical properties, and in another example, the irreversible molecular reconfiguration can cause the photosensitive dopant to reduce or turn off the electrical properties of the build material or inked powder layer (or layers).

In accordance with this, the present disclosure is drawn to photosensitive material sets, photosensitive build materials, and 3D printing systems, as disclosed and described herein. The photosensitive material set can include build material comprising polymeric particles having an average size from 10 μm to 100 μm and an average aspect ratio of less than 2:1, and an inkjettable fluid for application to the build material for 3D printing. The aspect ratio of less than 2:1 indicates that the particulate powder are substantially uniform in size, e.g., essentially round to moderately oval in size (i.e. aspect ratio defined by the longest axis to shortest axis of the particles, take as an average over the particulate population). The inkjettable fluid and/or the build material can include a photosensitive dopant have a first electrical property in a first chemical configuration and a second electrical property when modified to a second chemical configuration by exposure to photo electromagnetic radiation that is suitable to convert the photosensitive dopant from the first chemical configuration to the second chemical configuration. In one specific example, the inkjettable fluid can also be a fusible ink suitable for fusing the build material when printed thereon. However, in another example, the photosensitive material set can include a totally separate ink that acts as a fusible ink which is used to fuse the build material.

In another example, a photosensitive build material can include polymeric particles having an average size from 10 μm to 100 μm and an average aspect ratio of less than 2:1, and a photosensitive dopant blended with the polymeric particles. The photosensitive dopant can have a first electrical property m a first chemical configuration and a second electrical property when modified to a second chemical configuration by exposure to photo electromagnetic radiation that is suitable to convert the first chemical configuration to the second chemical configuration. In this example and others where there is a particulate build material, whether or not the photosensitive dopant is present in the build material or the inkjettable fluid or ink, the photosensitive build material can be in the form of a free-flowing particulate suitable for use as a powder bed build material for 3-D printing.

In another example, a 3D printing system can include a build material comprising polymeric particles having an average size from 10 μm to 100 μm and an average aspect ratio of less than 2:1, an inkjettable fluid suitable for application to the polymeric particles for 3D printing, a photosensitive dopant and a photo energy source for emitting the photo electromagnetic radiation onto the build material either before or after the inkjettable fluid is applied to the build material. The photosensitive dopant can be i) blended with the polymeric particles, ii) included in the inkjettable fluid, or iii) both. Again, the photosensitive dopant can have a first electrical property in a first chemical configuration and a second electrical property when modified to a second chemical configuration by exposure to photo electromagnetic radiation that is suitable to convert the photosensitive dopant from the first chemical configuration to the second chemical configuration. In this and other examples, the inkjettable fluid can also be part a fusible ink suitable for fusing the build material when printed thereon, or it can be a separate inkjettable fluid with respect to the fusible ink. The photo electromagnetic radiation can be UV energy, visible light energy, or IR energy, for example. For example, with the photosensitive dopant can be a charge transport molecule such as p-diethylaminobenzaldehyde diphenythydrazone; and the photo electromagnetic radiation can he UV energy. Other suitable charge transport molecules that can be used include anti-9-isopropylcarbazole-3-carbal-dehyde diphenylhydrazone, or tri-p-tolylamine.

In the present disclosure, it is noted that when discussing the photosensitive material set, or the photosensitive build material, or the 3D printing system, each of these discussions can be considered applicable to each of these examples, whether or not they are explicitly discussed in the context of that example. Thus, for example, in discussing details about the photosensitive material set or the photosensitive build material per se, such discussion also refers to the 3D printing system, and vice versa.

In examples of the present disclosure, this technology can be used with a wide variety of printing architecture, including piezo printing systems or thermal inkjet printing systems. In one example, HP's Multi Jet Fusion technology, which may utilize their innovative page-wide thermal inkjet (TIJ) printing technology, can be used, thus benefitting from drop-on-demand digital patterning making possible the printing at any location in a print zone at a high spatial resolution. High spatial resolution and “all-points-addressability” makes it possible to dispense a range of inks into and onto polymer media at the unit voxel scale, as mentioned. In the context of the present disclosure, this technology can be used with direct-write laser patterning techniques and can be used to photochemically tune the electrical properties provided by molecular dopants that have been blended into the structural powder (either by inkjettable fluid application, or by blending the dopant directly into the powder).

A general example of a 3D printing process begins with the application of a thin powder or particulate layer in the working zone of the printer. The powder can be selected from a set of polymers that possesses moderately low melting points (<200° C.), or higher melting points ranging from 200° C. to 500° C. For example, Nylon 12 (PA12) is one example of a suitable build material. Next, the powder layer surface is patterned with an ink that is typically an electromagnetic energy-absorbing ink (e.g. IR absorbing ink) or may provide coalescence simply by drying without added energy. In the case of energy-absorbing ink, once patterned, the powder layer is exposed to a high energy photo energy source that matches or overlaps the frequency at which the electromagnetic energy-absorbing ink is activated. For example, for an IR absorbing ink, an infra-red photo energy source can be used that selectively fuses regions that have been printed with the IR absorbing ink, leaving unprinted areas unchanged. The unfused powder can then be removed leaving behind a three-dimensional pattern. This layer-by-layer process can be repeated as many times as desired to produce a final three-dimensional component. It is to be noted that the energy-absorbing ink and IR energy used to fuse a fusible ink to a build material is not to be confused with the typically separate process of applying photo-energy to dopant to electrically modify dopant molecules. That can be a separate process using a different frequency of photo electromagnetic radiation. For example, the fusing energy might be IR energy and the dopant electrical activation or deactivation may be UV energy. That being said, there these frequencies could be closer together in wavelength (e.g., two different IR frequencies), or there could be applications where a common frequency might be used for both functions, but with different intensity, etc.

Turning now to the various technology for providing dopant to the build material, in accordance with one example of the present disclosure, an inkjettable fluid can be used as a delivery mechanism for dopant into the build material or powder medium, or the build material can be prepared that includes a particulate dopant blended with the polymeric particulates. In the case of delivering the dopant using an inkjettable fluid as the fluid penetrates into the build material, nanoparticles can become stranded on and between the polymer particles. At large enough volume fractions, the microscopic physical properties such as the conductivity of the doped voxel can be modified. This scheme is shown generally in FIG. 11 for example.

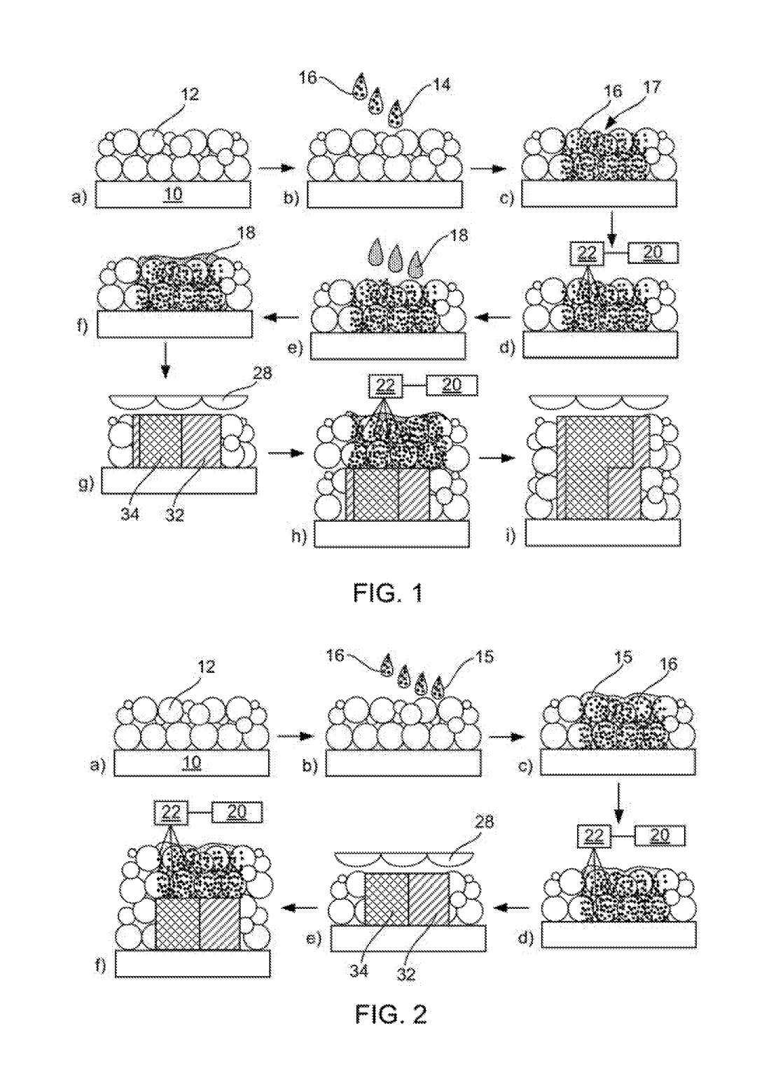

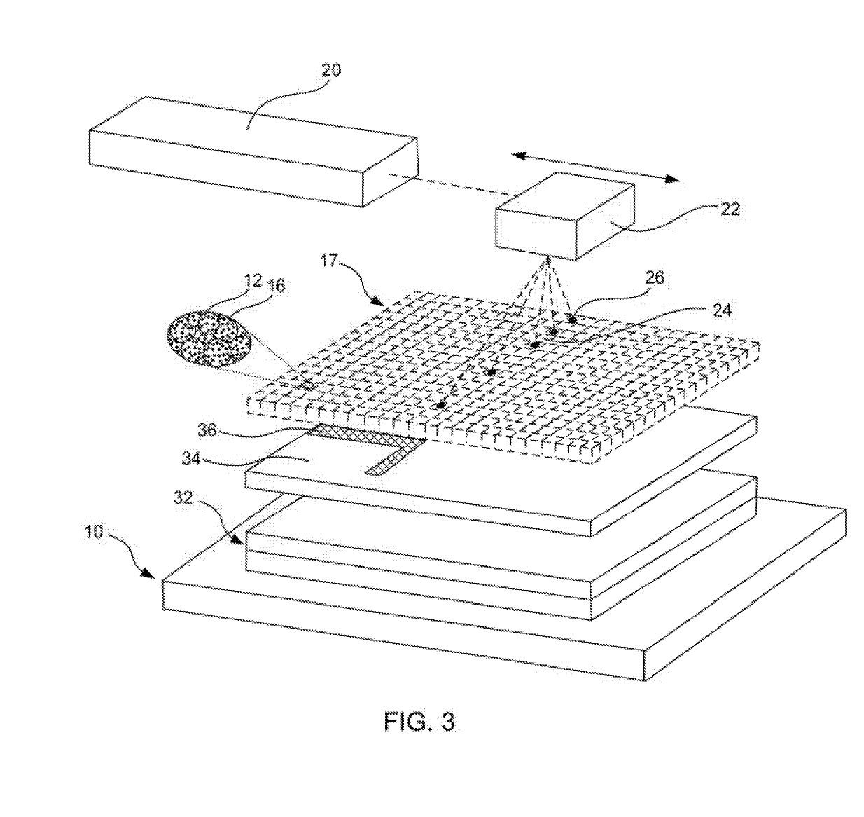

More specifically, in FIG. 1, a system is shown in accordance with examples of the present disclosure. It is noted that there are 9 steps shown (a-i) in FIG. 1 that exemplify aspects of the system, but this is done merely for convenience in describing on possible process. Additionally, similar structures shown in each of the 9 steps (a-i) are labeled with reference numerals once or twice, but such references are applicable throughout all of FIG. 1 for clarity if viewing and understanding the FIG. Thus, in FIG. 1, a) shows substrate or build platform 10 which has a thin layer of build material which in this case are polymeric particles 12 deposited thereon. In other words, the particulate build material in this example is spread in a thin layer on the build platform. Next, b) shows microdroplets 14 of an inkjettable fluid containing electrically modifiable dopant. The droplets are printed on the build material, and as the liquid vehicle evaporates, the dopant becomes stranded on the build material particles to form a doped build material 17, as shown at c). In accordance with the present disclosure, as shown at d), the doped build material is then selectively energized using a photo energy source 20, which can be a UV laser for example, depending on the sensitivity of the dopant. The photo energy source beams the laser into a scanning or photo imaging unit 22, such as an all-points-addressable scanning unit, to selectively electrically modify desired portions of the dopant. By selectively turning on or turning off the electrical properties (or partially turning on/off in the case of generating a semi-conductor), various electrical functionality can be printed into the 3D part that is being formed. A fusible ink 18, shown at e) and f), is then printed onto the portion of the particulate build material that will form the structure of the part. In this example, the fusible ink does not include dopant, but is the ink that fuses with the particulate build material (usually under a different frequency of photo electromagnetic radiation, such as IR energy from an IR energy source 28) to form the 3D structure. Thus, for clarify, the inkjettable fluid with dopant combined with the UV energy in this example provide the electrical functional differentiation between various doped areas (some energized by UV and some not), and the fusible ink is used for the structure building per se. That being stated, there are examples where the inkjettable fluid with dopant can also be the same ink as the fusible ink. In such cases, such as shown in FIG, 2, the dopant would be selectively developed after applying the fusible ink 15 (which includes the dopant 16). In FIG. 2, the reference numerals and description can be essentially the same, other than this difference regarding jetting the dopant with the fusible ink. Returning now to FIG. 1, but also applicable to FIG. 2. After developing a selective portion of the dopant and after fusing the fusible ink with the particulate build material, a solid part 32, 34 is formed that has two regions of electrical conductivity, shown at 32 (undeveloped) and 34 (developed). This is shown at g) in FIG. 1 and e) in FIG. 2. Once this layer is formed, the process is repeated to add an additional layer, shown in summary at h) and i) in FIG. 1 and at f) in FIG. 2, and so forth. As a note, the terms “developed” and “undeveloped” above can be a function of degree. For example, by adjusting the volume fraction of dopants in each layer either by using inks with different photosensitive dopant concentrations or by multiple print passes (i.e. overprinting) to increase the volume fraction directly, electrical conductivity can be graded vertically or horizontally. For example, the electrical conductivity can be graded from high to low (or vice versa) by adjusting the dopant volume fraction and/or photo-converting each subsequent layer in a vertical column or axis.

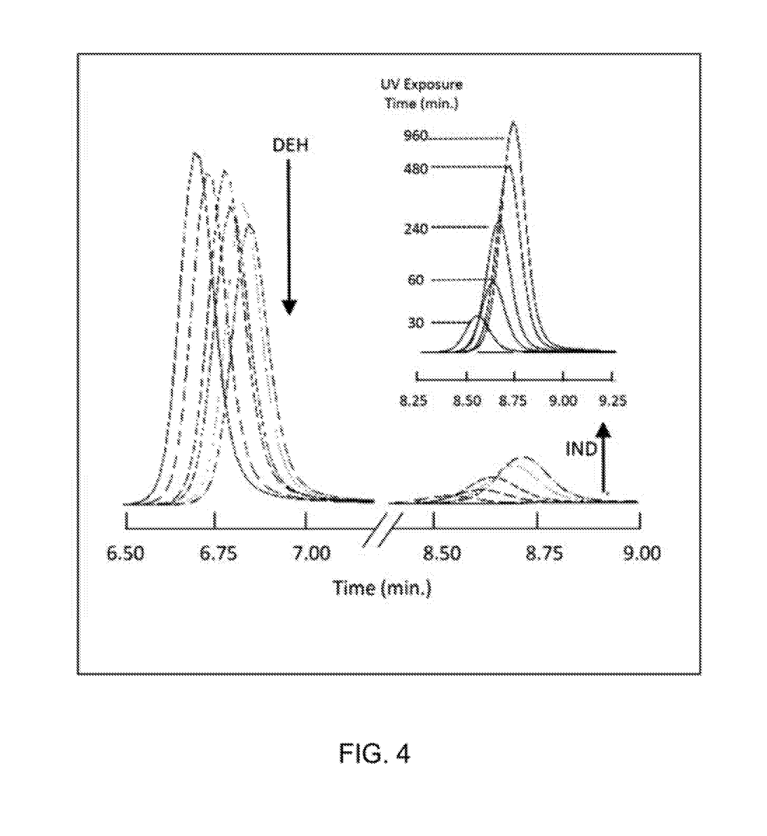

Alternatively, unlike the inkjet doping processes discussed above, as shown in FIG. 3, dopant 16 can be homogeneously distributed uniformly throughout a polymeric powder 12 to form a doped build material 17 layer. In other words, the entire powder layer can be blended with photoactive dopant material. Thus, when forming the 3D part, on a layer by layer basis, or at any surface or near surface location at any time during the process, dopant present at spatially localized regions of the powder surface can be converted from a first molecular configuration 24 to another to a second molecular configuration 26 directly using a focused light source (or photo energy source), such as a laser 20 and an optically coupled scanning or photo imaging unit 22. For example, the scanning unit can be used to scan laser energy across the surface of the powder layer, voxels or sub-voxel regions (shown not to scale at 24 and 26), and the voxels or sub voxels can be individually addressed and photoactivated (causing enhanced electrical or decreased electrical conductivity). Thus, the process shown in FIG. 3 is similar to that shown in FIG. 1, except that the dopant is premixed or dry blended with the polymeric particle build material rather than dispensed to the into the layers of build material using an inkjettable fluid. In such examples, the polymeric powder and the photosensitive dopant blend can be said to be pre-adapted for selective electrical modification. The use of a fusible ink to build and bind the various layers together (shown at 32) is also shown in FIG. 1. Each of the layers can be selectively modified in its electrical properties as previously described. Unmodified dopant portions are shown at 34 and modified portions are shown at 36 in FIG. 3.

In one specific example, scanning or photo imaging unit 22 shown in FIGS. 1-3 can be an all-points-addressable, direct-write imaging system used for electrically modifying a composite powder layer. There, an unfused powder layer is optically addressed directly using a laser photo energy source and an all-points-addressable scanning unit. This addressing scheme can be similar to the scanning methods used in modern electrophotographic printers; however, instead of forming an electrostatic latent image on the surface of a photoreceptor, in this process, the directed light beam is used to induce a photochemical reaction of light sensitive dopants that have been dispersed into the unfused powder blend. Once fused, the voxels that have been optically addressed are modified to possess different electrical properties than neighboring regions and layers.

In either case, whether the dopant is added to the build material using inkjet technology, or the dopant is dry blended or otherwise incorporated with the build material initially, the dopant can be a charge transport (CT) material. These CT materials or additives can be combined with the polymeric particle build material (e.g., a polycarbonate, polystyrene or similar polymer powders) to form a dry blended doped composite. A specific molecular dopant that can be used includes p-diethylaminobenzaldehyde diphenylhydrazone (DEH), which undergoes irreversible molecular reconfiguration when exposed to ultra-violet (UV) light. For example, it has been experimentally observed that exposure of molecularly doped polymer (MDP) containing DEH to ultraviolet (UV) light produces an irreversible conversion of the DEH molecules to the photo-cyclization product, 1-phenyl-3-(4-diethylamino-1,3-indazole (IND). Furthermore, optical absorption spectra, which show an isosbestic point at ˜300 nm, indicate that the IND reaction product is the only photoproduct produced during the reaction. In other words, prolonged exposure to UV light in air results in a systematic conversion of DEH molecules to IND molecules. Since electronic conduction in molecularly doped polymers occurs via a variable range hopping process, the systematic conversion of DEH molecules to the IND derivative (parametric in wavelength and exposure time) effectively removes hopping sites from the charge transport manifold rendering the film progressively more electrically insulating. Thus, by using UV radiation on this molecule, electrical properties can be “turned off” or reduced in certain discrete portions of the powder during the build, effectively proving an approach to provide active an inactive sites for electron hopping to occur. In other words, DEH causes electrical conducting properties that can be turned off by exposing to UV light. In some instances, electrical properties can be activated by exposing to focused radiation, and in other cases, electrical properties maybe deactivated (like with DEH) by exposing to focused light (this will depend on the dopant selected for use). Additionally, time or intensity of focused light can determine the rate or magnitude of the electrical property changes as well. For example, for a unit volume or voxel, the voxel's ensemble conductivity can be systematically reduced by adjusting the UV exposure time. With the ability to “program” the surface conductivity of a printed layer on a voxel-by-voxel basis (in some examples without interrupting the pricing process if modifying as each layer is put down), new electronic functions (or lack thereof) can be enabled, For example, new functionalities or properties can be imparted to the printed part, such as electrical conductivity, insulating properties, semiconducting properties, and/or antistatic properties. Other photosensitive dopants can be modified chemically using photo energy (and thus electrically based on electron hopping increase or decrease) in accordance with their unique chemical mechanisms/reaction schemes.

Turning now to the inkjet inks that can be used with the present disclosure, it is notable that the inkjet ink may or may not contain the photosensitive dopant. The photosensitive dopant may be present in a fusible ink that is used to form harden the build material, or the photosensitive dopant may be present in a separate pre-treatment ink that is predispensed (see FIG. 1) prior to application of the fusible ink, or the photosensitive dopant may be present as a blend within the polymeric polymer build material (see FIG. 3). In either case, in examples of the present disclosure, a fusible ink can he used that is printed on the build material to solidify the build material for layer 3D part building. This ink can include, for example, a pigment or dye colorant that imparts a visible color to the ink. In some examples, the colorant can be present in an amount from 0.1 wt % to 10 wt % In the ink. In one example, the colorant can be present in an amount from 0.5 wt % to 5 wt %. In another example, the colorant can be present in an amount from 5 wt % to 10 wt %. However, the colorant, is optional end in some examples the ink can include no additional colorant. These inks can be used to print 3D parts that retain the natural color of the polymer powder. Additionally, the ink can include a white pigment such as titanium dioxide that can also impart a white color to the final printed part. Other inorganic pigments such as alumina or zinc oxide can also be used.

In some examples, the colorant can be a dye. The dye may be nonionic, cationic, anionic, or a mixture of nonionic, cationic, and/or anionic dyes. Specific examples of dyes that may be used include, but are not limited to. Sulforhodamine B, Acid Blue 113, Acid Blue 29, Acid Red 4, Rose Bengal, Acid Yellow 17, Acid Yellow 29, Acid Yellow 42, Acridine Yellow G, Acid Yellow 23, Acid Blue 9, Nitro Blue Tetrazolium Chloride Monohydrate or Nitro BT, Rhodamine 6G, Rhodamine 123, Rhodamine B, Rhodamine B Isocyanate, Safranine O, Azure B; and Azure B Eosinate, which are available from Sigma-Aldrich Chemical Company (St. Louis, Mo.). Examples of anionic, water-soluble dyes include, but are not limited to, Direct Yellow 132, Direct Blue 199, Magenta 377 (available from Ilford AG, Switzerland), alone or together with Acid Red 52. Examples of water-insoluble dyes include azo, xanthene, methine, polymethine, and anthraquinone dyes. Specific examples of water-insoluble dyes include Orasol® Blue GN, Orasol® Pink and Orasol® Yellow dyes available from Giba-Geigy Corp. Black dyes may include, but are not limited to, Direct Black 154, Direct Black 168, Fast Black 2, Direct Black 2.

In other examples the colorant can be a pigment. The pigment can be self-dispersed With a polymer, oligomer, or small molecule; or can be dispersed with a separate dispersant. Suitable pigments include, but are not limited to, the following pigments available from BASF: Paliogen®) Orange, Heliogen® Blue L 6901F: Heliogen®) Blue NBD 7010, Heliogen® Blue K 7090, Heliogen® Blue L 7101F, Paliogen®) Blue L 6470, Heliogen®) Green K 8683, and Heliogen® Green L 9140. The following black pigments are available from Cabot: Monarch® 1400, Monarch® 1300, Monarch®) 1100, Monarch® 1000, Monarch®) 900, Monarch® 880, Monarch® 800, and Monarch®) 700. The following pigments are available from CIBA: Chromophtal®) Yellow 3G, Chromtophtal®) Yellow GR, Chromophtal®) Yellow 8G, Igrazin® Yellow 5GT, Igralite® Rubine 4BL, Monastral® Magenta, Monastral® Scarlet, Monastral® Violet R, Monastral® Red B, and Monastral® Violet Maroon B. The following pigments are available from Degussa: Printex® U, Printex® V, Printex® 140U, Printex® 140V, Color Black FW 200. Color Black FW 2, Color Black FW 2V; Color Black FW 1, Color Black FW 18, Color Black S 160, Color Slack S 170, Special Black 6, Special Black 5, Special Black 4A, and Special Black 4. The following pigment is available from DuPont: Tipure®) R-101. The following pigments are available from Heubach: Dalamar® Yellow YT-858-D and Heucophthal Blue G XBT-583D. The following pigments are available from Clariant: Permanent Yellow GR, Permanent Yellow G, Permanent Yellow DHG, Permanent Yellow NCG-71, Permanent Yellow GG, Hansa Yellow RA, Hansa Brilliant Yellow 5GX-02, Hansa Yellow-X, Novoperm®) Yellow HR, Novoperm® Yellow FGL Hansa Brilliant Yellow 10GX, Permanent Yellow G3R-01, Hostaperm® Yellow H4G; Hostaperm® Yellow H3G, Hostaperm® Orange GR, Hostaperm® Scarlet GO, and Permanent Rubine F6B. The following pigments are available from Mobay: Quindo® Magenta, Indofast® Brilliant Scarlet, Quindo® Red R6700, Quindo® Red R6713, and Indofast® Violet. The following pigments are available from Sun Chemical: L74-1357 Yellow, L75-1331 Yellow, and L75-2577 Yellow. The following pigments are available from Columbian; Raven® 7000, Raven® 5750, Raven® 5250, Raven® 5000, and Raven® 3500. The following pigment Is available from Sun Chemical: LHD9303 Black. Any other pigment and/or dye can be used that is useful in modifying the color of the coalescent ink and/or ultimately, the printed part.

The colorant can be included in the ink to impart color to the printed object when the coalescent ink is jetted onto the powder bed. Optionally, a set of differently colored inks can be used to print multiple colors. For example, a set of inks including any combination of cyan, magenta, yellow (and/or any other colors), colorless, white, and/or black inks can be used to print objects in full color. Alternatively or additionally, a colorless ink can be used in conjunction with a set of colored inks to impart color. In some examples, a colorless ink can be used to coalesce the polymer powder and a separate set of colored or black or white inks can be used to impart color. The components of a fusible ink and/or a pre-treatment ink can be selected to give the ink good ink jetting performance, and in the case of the fusible ink typically, the ability to color the polymer powder with good optical density.

In any of the inks described herein (inkjettable fluid used to deposit dopant and/or fusible ink used to harden polymeric layers), the ink can include a liquid vehicle. In some examples, the liquid vehicle formulation can be water, or water and one or more co-solvent present in total at from 1 wt % to 50 wt % (of co-solvent), depending on the jetting architecture. Further, one or more non-ionic, cationic, and/or anionic surfactant can optionally be present, ranging from 0.01 wt % to 20 wt %. In one example, the surfactant can be present in an amount from 5 wt % to 20 wt %. The liquid vehicle can also include dispersants in an amount from 5 wt % to 20 wt %. In addition to the water, the balance of the formulation can be other vehicle components such as biocides, viscosity modifiers, materials for pH adjustment, sequestering agents, preservatives, and the like. In one example, the liquid vehicle can be predominantly water. In some examples, a water-dispersible polymer can be used with an aqueous vehicle. In some examples, the ink can be substantially free of organic solvent. However, In other examples, a co-solvent can be used to help dissolve or disperse dyes or pigments, or improve the jetting properties of the ink, or for other purposes. In still further examples, a non-aqueous vehicle can be used.

Classes of co-solvents that can be used can include organic co-solvents including aliphatic alcohols, aromatic alcohols, diols, glycol ethers, polyglycol ethers, caprolactams, formamides, acetamides, and long chain alcohols. Examples of such compounds include primary aliphatic alcohols, secondary aliphatic alcohols, 1,2-alcohols, 1,3-alcohol, 1,5-alcohols, ethylene glycol alkyl ethers, propylene glycol alkyl ethers, higher homologs (C₆-C₁₂) of polyethylene glycol alkyl ethers, N-alkyl caprolactams, unsubstituted caprolactams, both substituted and unsubstituted formamides, both substituted and unsubstituted acetamides, and the like. Specific examples of solvents that can be used include, but are not limited to, 2-pyrrolidinone, N-methylpyrrolidone, 2-hydroxyethyl-2-pyrrolidone, 2-methyl-1,3-propanediol, tetraethylene glycol, 1,6-hexanediol, 1,5-hexanediol and 1,5-pentanediol.

In certain examples, a co-solvent or liquid vehicle can be formulated in general that has a high vapor pressure. In such example, the high vapor pressure vehicle or vehicle components can be formulated to thus evaporate quickly, leaving the DEH stranded on the polymer particles when dispensed on the particulate build material.

One or more surfactants can also be used, such as alkyl polyethylene oxides, alkyl phenyl polyethylene oxides, polyethylene oxide block copolymers, acetylene polyethylene oxides, polyethylene oxide (di)esters, polyethylene oxide amines, protonated polyethylene oxide amines, protonated polyethylene oxide amides, dimethicone copolyols, substituted amine oxides, and the like. The amount of surfactant added to the formulation of this disclosure may range from 0.01 wt % to 20 wt %. Suitable surfactants can include, but are not limited to, liponic esters such as Tergitol™ 15-S-12. Tergitol™ 15-S-7 available from Dow Chemical Company. LEG-1 and LEG-7; Triton™ X-100; Triton™ X-405 available from Dow Chemical Company; and sodium dodecylsulfate.

Consistent with the formulation of this disclosure, various other additives can be employed to provide desired properties to the ink(s) for specific applications. Examples of these additives are those added to inhibit the growth of harmful microorganisms. These additives may be biocides, fungicides, and other microbial agents, which are routinely used in ink formulations. Examples of suitable microbial agents include, but are not limited to, NUOSEPT® (Nudex, Inc.), UCARCIDE™ (Union carbide Corp.), VANCIDE® (R.T. Vanderbilt Co.), PROXEL® (ICI America), and combinations thereof.

Sequestering agents, such as EDTA (ethylene diamine tetra acetic acid), may be included to eliminate the deleterious effects of heavy metal impurities, and buffer solutions may be used to control the pH of the ink. From 0.01 wt % to 2 wt %, for example, can be used. Viscosity modifiers and buffers may also be present, as well as other additives to modify properties of the ink as desired. Such additives can be present at from 0.01 wt % to 20 wt %.

Regardless of how the photosensitive dopant is brought to the build material (dry blended or by inkjet printing), the fusible ink can typically include an antenna compound or polymer that has a peak absorption wavelength in the IR range, in one example, e.g., from 800 nm to 1400 nm. This can enable hardening of the build material under IR energy when combined with the fusible ink, while leaving the unprinted portions of the build material as a powder. Thus, in one example, the build material can include a particulate polymer formulated to coalesce when contacted by the ink and irradiated by a near-IR or IR energy emitting the peak absorption wavelength.

The particulate polymer in the build material can have an average particle size from 10 μm to 100 μm, as mentioned. The particles can have a variety of shapes, such as substantially spherical particles, or substantially oval or irregularly-shaped particles up to an average 2:1 aspect ratio (long axis to shortest axis). In some examples, the polymer powder can be capable of being formed into 3D printed parts with a resolution of 10 μm to 100 μm. As used herein, “resolution” refers to the size of the smallest feature that can be formed on a 3D printed pail. The polymer powder can form layers from about 10 μm to 100 μm thick, allowing the coalesced layers of the printed part to have roughly the same thickness. This can provide a resolution in the axis direction of about 10 μm to 100 μm. The polymer powder can also have a sufficiently small particle size and sufficiently regular particle shape to provide about 10 μm to 100 μm resolution along the x-axis and y-axis.

The polymeric particles of the build material can have a melting or softening point from about 70° C. to about 350° C. In further examples, the polymer can have a melting or softening point from about 150° C. to about 200° C. A variety of thermoplastic polymers with melting points or softening points in these ranges can be used. For example, the particulate polymer can be selected from the group consisting of nylon 6 powder, nylon 9 powder, nylon 11 powder, nylon 12 powder, nylon 68 powder, nylon 612 powder, polyethylene powder, thermoplastic polyurethane powder, polypropylene powder, polyester powder, polycarbonate powder, polyether ketone powder, polyacrylate powder, polystyrene powder, and mixtures thereof. In a specific example, the particulate polymer can be nylon 12, which can have a melting point from about 175° C. to about 200° C. In another specific example, the particulate polymer can be thermoplastic polyurethane.

In further detail regarding the powder bed or build material generally, the entire powder bed, or a portion of the powder bed, can be preheated to a temperature below the melting or softening point of the polymer powder. In one example, the preheat temperature can be from about 10° C. to about 70° C. below the melting or softening point. In another example, the preheat temperature can be within 50° C. of the melting of softening point. In a particular example, the preheat temperature can be from about 160° C. to about 170° C. and the polymer powder can be nylon 12 powder. In another example, the preheat temperature can be about 90° C. to about 10° C. and the polymer powder can be thermoplastic polyurethane. Preheating can be accomplished with one or more lamps, an oven, a heated support bed, or other types of heaters. In some examples, the entire powder bed can be heated to a substantially uniform temperature.

As mentioned, in one example, the powder bed can be irradiated with a fusing lamp configured to emit a wavelength from 800 nm to 1400 nm. Suitable fusing lamps can include commercially available infrared lamps and halogen lamps. The fusing lamp can be a stationary lamp or a moving lamp. For example, the lamp can be mounted on a track to move horizontally across the powder bed. Such a fusing lamp can make multiple passes over the bed depending on the amount of exposure needed to coalesce each printed layer. The fusing lamp can be configured to irradiate the entire powder bed with a substantially uniform amount of energy.

Regarding relative concentrations of the photosensitive dopant in the material sets of the present disclosure, these concentrations can depend on the specific material set in which the dopant is used. For example, with the photosensitive build material (for the powder bed per se), the polymeric particles to photosensitive dopant particles can be blended at a weight ratio of 99:1 to 2:1, or from 20:1 to 3:1, or from 15:1 to 4:1, depending on how photosensitive or “electrically active the blend should be for a particular application. One factor, for example, with respect to the photosensitive dopant concentration in the powder bed relates to the overall fusing properties of the photosensitive build material. Too much photosensitive dopant blended with the fusing polymer can diminish the ability of the polymer to fuse. Thus, though the weight ratios shown above are not considered limiting, these ratios provide a good range for providing desirable fusing properties and photosensitive/electrical properties.

On the other hand, when discussing inks that carry the photosensitive dopant to the build material, various concentration of photosensitive dopant can be used. For example, in an inkjettable fluid that is used primarily to dope the build material (not part of the fusible ink), a range of photosensitive dopant in the fluid can be from 5 wt % to 60 wt %, from 10 wt % to 50 wt %, or from 15 wt % to 40 wt %. The balance can be water or other liquid vehicle, e.g., water admixed with solvent such as toluene or any other liquid vehicle described herein in generally. In some example, a high vapor pressure solvent can be present that may be more readily removed when printed into a powder bed. In examples where the photosensitive dopant is used in a build or fusible ink, similar concentrations can be used, with the caveat that when other solids are present in the formulation, such as pigment slightly lower concentrations of photosensitive agent may be desirable. In certain examples where a pigment is present for fusing (e.g., carbon black) and/or for coloration of the ink, a combination of pigment to photosensitive agent may be present at a 1:2 to 9:1 weight ratio, a 1:1 to 8:1 weight ratio, or a 2:1 to 7:1 weight ratio.

Furthermore, when using photosensitive dopant in an inkjettable fluid or ink, in some examples, the particle size of the photosensitive dopant can be reduced by grinding or milling to achieve a particle size suitable for inkjetting from thermal or other jetting architecture. To illustrate, as DEH can be powder form as an agglomerate of many smaller colloids, the particle size can be readily reduced by grinding so that the particles are at a similar particle size as the pigment or other solids that may be present in the inkjettable fluid or ink, e.g., sub-micron or less than a micron in size.

It is to be understood that this disclosure is not limited to the particular process steps and materials disclosed herein because such process steps and materials may vary somewhat. It is also to be understood that the terminology used herein is used for the purpose of describing particular examples only. The terms are not intended to be limiting because the scope of the present disclosure is intended to be limited only by the appended claims and equivalents thereof.

It is noted that, as used in this specification and the appended claims, the singular forms “a,” “an,” and “the” include plural referents unless the context clearly dictates otherwise.

As used herein, “liquid vehicle” or “ink vehicle” refers to a liquid fluid in which additive is placed to form an ink or an inkjettable fluid. A wide variety of ink vehicles may be used with the systems and methods of the present disclosure. Such ink vehicles may include a mixture of a variety of different agents, inducting, surfactants, solvents, co-solvents, anti-kogation agents, buffers, biocides, sequestering agents, viscosity modifiers, surface-active agents, water, etc. Though not part of the liquid vehicle per se, in addition to the colorants and/or polymers that may be included, the liquid vehicle can carry solid additives such as polymers, latexes, UV curable materials, plasticizers, salts, etc. In some example, the additive earned by the liquid vehicle can be the photosensitive dopant as described herein.

The terms “fusible ink” and “inkjettable fluids” are used herein to describe fluids that are jettable from inkjet architecture, such as from thermal inkjet or piezo inkjet printing systems. The term “fusible ink” refers to inks that are jetted onto particulate build material for solidifying or fusing the build material to form a layer of a 3D part. Typically, the fusible ink includes an additive that becomes energized or heated when exposed to a frequency or frequencies of electromagnetic radiation. For example, carbon black can act as both a colorant and additive that fuses with the build material when irradiated with broad spectrum IR radiation. Other additives can be alternatively or additionally be used, such as conjugated polymers, IR dyes, or the like. Any additive that assists in fusing the ink with the build material to form the 3D part can be used in the fusible ink. A fusible ink can in some examples, also include the photosensitive dopants described herein. The term “inkjettable fluid” is used herein to describe fluids that include the photosensitive dopant, but which are not necessarily fusible inks per se. These fluids are used to dope the particulate build material prior to applying the fusible ink and electromagnetic radiation.

As used herein, “colorant” can include dyes and/or pigments.

As used herein, “dye” refers to compounds or molecules that absorb electromagnetic radiation or certain wavelengths thereof. Dyes can impart a visible color to an ink if the dyes absorb wavelengths in the visible spectrum.

As used herein, “pigment” generally includes pigment colorants, opaque particles, magnetic particles, aluminas, silicas, and/or other ceramics, organo-metallics, nanoparticles, nanowires, or nanotubes, whether or not such particulates impart color. Thus, though the present description primarily exemplifies the use of pigment colorants. the term “pigment” can be used more generally to describe not only pigment colorants, but other pigments such as organometallics, ferrites ceramics, etc. In one specific aspect, however, the pigment is a pigment colorant.

As used herein, “jet,” “jettable,” “jetting,” or the like refers to compositions that are ejected from jetting architecture, such as inkjet architecture, inkjet architecture can include thermal or piezo architecture. Additionally, such architecture can be configured to print varying drop sizes such as less than 10 picoliters, less than 20 picoliters, less than 30 picoliters, less than 40 picoliters, less than 50 picoliters, etc.

As used herein, the term “substantial” or “substantially” when used in reference to a quantity or amount of a material, or a specific characteristic thereof, refers to an amount that is sufficient to provide an effect that the material or characteristic was intended to provide. The exact degree of deviation allowable may in some cases depend on the specific context.

As used herein, the term “about” is used to provide flexibility to a numerical range endpoint by providing that a given value may be “a little above” or “a little below” the endpoint. The degree of flexibility of this term can be dictated by the particular variable and determined based on the associated description herein.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include individual numerical values or sub-ranges encompassed within that range as if each numerical value and sub-range is explicitly recited. As an illustration, a numerical range of “about 1 wt % to about 5 wt %” should be interpreted to include not only the explicitly recited values of about 1 wt % to about 5 wt %, but also include individual values and sub-ranges within the indicated range. Thus, included in this numerical range are individual values such as 2: 3.5, and 4 and sub-ranges such as from 1-3, from 2-4, and from 3-5, etc. This same principle applies to ranges reciting only one numerical value. Furthermore, such an interpretation should apply regardless of the breadth of the range or the characteristics being described.

### EXAMPLES

The following illustrates several examples of the present disclosure. However, it is to be understood that the following are only illustrative of the application of the principles of the present disclosure. Numerous modifications and alternative compositions, methods, and systems may be devised without departing from the spirit and scope of the present disclosure. The appended claims are intended to cover such modifications and arrangements.

### Example 1—Conversion of DEH into IND Derivative

To determine the effectiveness of converting p-diethylaminobenzaldehyde diphenylhydrazone (DEH) to its photo-cyclization product, 1-phenyl-3-(4-diethylamino-1 phenyl)-1,3-indazole (IND), under ultra-violet (UV) light coating solutions were prepared by dissolving DEH and a bisphenol-A-polycarbonate (PC) in HPLC-grade tetrahydrofuran (i.e. using 40 wt % concentrations of DEH). Samples were prepared by solvent coating the solutions onto semitransparent aluminized Mylar® substrates. The coated substrates were oven dried, in air, at 100° C. for 1 hour to reduce residual solvent content. With the exception of control samples, which received no irradiation, films were uniformly exposed to UV light using a 15-W Phillips BLB fluorescent lamp. The peak spectral output of this lamp was between 350 and 390 nm. The incident exposure power was measured by a United Detector Technology Model 351 optical power meter. The incident energy was determined to be 0.13 J/cm² per minute of exposure. The exposure times ranged from 30 to 960 min. Counterelectrodes were deposited onto the free surfaces of the films using an electron beam evaporation process. The electrodes were 1 cm in diameter and consisted or 2000 Å of aluminum. All samples, were annealed well above the glass transition temperature of the film (100° C.) for 3 hours to homogeneously redistribute the DEH molecules and eliminate damage caused by the metal deposition step. The thickness of each sample was determined by capacitance and precision step height measurements. Typical film thicknesses were between 10 and 10.5 μm. High performance liquid chromatography (HPLC) spectra obtained from DEH-doped PC films before and after systematic UV irradiation are shown in FIG. 4.

With the exception of the counterelectrode deposition and post-deposition annealing, the samples used in the HPLC measurements were prepared identically to those used in the time-of-flight measurements. In the plot, peaks at two well-separated retention times are observed. The peak at 6.75 min. is attributed to DEH and decreased with increasing UV exposure times. Authentic DEH reference samples were used to confirm that the peak at 6.75 minutes is associated with the DEH chemical compound. The peak at 8.75 minutes begins to grow systematically with UV exposure as shown in the inset. Chromatographic data indicates that this peak is associated with the imidazole photoproduct.

DC charge transport can be measured using the photostimulated time-of-flight method. During the measurement the film sample acts as a parallel plate capacitor. Under a constant voltage bias, a 337 nm, 10 ns light pulse is delivered through the transparent bottom electrode. The strongly absorbed light pulse photogenerates a narrow packet of free charges that drift across the sample in response to the external electric field. In this experiment, the majority carriers were holes.

Based on the HPLC chromatographic data and the observed relationship of the mobility and UV exposure time, it is noted that prolonged UV exposure induces an irreversible conversion of the DEH molecules into an IND derivative. Since the IND molecules cannot participate in the charge transport process, the systematic conversion of the DEH molecules effectively removes active charge-hopping sites from the charge transport manifold transforming a semiconductive film to an insulator.

### Example 2—Photosensitive Build Material

A photosensitive build material is prepared by dry blending small nanoparticles of p-diethylaminobenzaldehyde diphenylhydrazone (DEH) particles (H. W. Sands) with nylon (PA12) particles (Vestosini® x1556). The nylon particles have an average particle diameter of approximately 50 μm and the DEH powder particles is about the same size as an agglomerate of many smaller particles. In some examples, the DEH may be reduced in size by grinding, if desired. Regardless what size powder of DEH is used, the molecular weight and density is typically about 343 g/mol and 1.08 g/cm³, respectively. The blend has a weight ratio of nylon particles to DEH of about 4:1.

### Example 3—Photosensitive Pre-Treatment Inkjettable Fluid

A photosensitive inkjettable fluid for jetting into build material of polymer powder for photosensitizing the polymer powder is prepared comprising 60 wt % liquid vehicle (e.g., toluene and a majority of water), and 40 wt % p-diethylaminobenzaldehyde diphenylhydrazone (DEH). In one example, the DEH is ground down to a sub-micron size appropriate for thermal inkjet printing.

### Example 4—Photosensitive Fusible Ink

A photosensitive fusible ink for jetting into build material of polymer powder for photosensitizing and fusing the polymer powder is prepared including 60 wt % liquid vehicle (e.g., toluene and water) and 40 wt % solids which includes carbon black pigment and p-diethylaminobenzaldehyde diphenylhydrazone (DEH) at a 3:2 weight ratio, in one example, the DEH is ground down to a sub-micron size appropriate for thermal inkjet printing.

### Example 5—System with Photosensitive Build Material

The photosensitive build material of Example 2 can be used in the system shown in FIG. 3; along with a fusible ink including carbon black pigment. The fusible ink can be formulated to fuse upon exposure to broad spectrum IR electromagnetic radiation for fusing the build material. This typically occurs after a selected portion of the photosensitive dopant in specified areas are selectively electrically modified (electron hopping properties modified) with UV electromagnetic radiation, e.g., laser energy. The process can be repeated on a layer by layer basis to build a part with electrical properties at desired locations.

### Example 6—System with Photosensitive Pre-Treatment Inkjettable Fluid

The photosensitive inkjettable fluid of Example 3 can be applied to a build material of polymer powder as shown in FIG. 1. Once applied, a selected portion of the photosensitive dopant in specified areas are selectively modified with UV electromagnetic radiation, e.g., laser energy. A fusible ink (without photosensitive dopant, but including carbon black pigment) can then be applied to the build material to fuse therewith upon exposure to broad spectrum IR electromagnetic radiation. The process can be repeated on a layer by layer basis to build a part with electrical properties at desired locations.

### Example 7—System with Photosensitive Fusible Ink

The photosensitive fusible ink with both photosensitive dopant and carbon black pigment of Example 4 can be applied to a build material polymer powder, as shown in FIG. 2. Once applied, a selected portion of the photosensitive dopant in specified areas are selectively modified with UV electromagnetic radiation, e.g., laser energy. Then, broad spectrum IR electromagnetic radiation can be applied to the inked polymer powder to fuse the build material. The process can be repeated on a layer by layer basis to build a part with electrical properties at desired locations.

What is claimed is:

1. A photosensitive material set, comprising:
build material comprising polymeric particles having an average size from 10 μm to 100 μm and an average aspect ratio of less than 2:1,
an inkjettable fluid for application to the build material for 3D printing, and
a photosensitive dopant i) blended with the polymeric particles, ii) included in the inkjettable fluid, or iii) both, wherein the photosensitive dopant has a first electrical property in a first chemical configuration and a second electrical properly when modified to a second chemical configuration by exposure to photo electromagnetic radiation that is suitable to convert the photosensitive dopant from first chemical configuration to the second chemical configuration.

2. The photosensitive material set of claim 1, wherein the inkjettable fluid is a fusible ink suitable for fusing the build material when printed thereon.

3. The photosensitive material set of claim 1, wherein the inkjettable fluid includes the photosensitive dopant, and the material set further comprises a fusible ink that is separate from the inkjettable fluid.

4. The photosensitive material set of claim 1, wherein the photosensitive dopant is blended with the polymeric particles.

5. The photosensitive material set of claim 1, wherein the photosensitive dopant include p-diethylaminobenzaldehyde diphenylhydrazone, anti-9-isopropylcarbazole-3-carbal-dehyde diphenylhydrazone, or tri-p-tolylamine.

8. The photosensitive material set of claim 1, wherein the first electrical property provides for greater charge hopping and mobility compared to the second electrical property.

7. The photosensitive material set of claim 1, wherein the second electrical property provides for greater charge hopping and mobility compared to the first electrical property.

8. A photosensitive build material, comprising:
polymeric particles having an average size from 10 μm to 100 μm and an average aspect ratio of less than 2:1; and
photosensitive dopant blended with the polymeric particles, wherein the photosensitive dopant has a first electrical property in a first chemical configuration and a second electrical property when modified to a second chemical configuration by exposure to photo electromagnetic radiation that is suitable to convert the first chemical configuration to the second chemical configuration.

9. The photosensitive particulate blend of claim 8, wherein the polymeric particles include a nylon, a thermoplastic elastomer, a urethane, a polycarbonate, or a polystyrene.

10. The photosensitive particulate blend of claim 8, wherein the photosensitive dopant includes p-diethylaminobenzaldehyde diphenylhydrazone, anti-9-isopropylcarbazole-3-carbal-dehyde diphenylhydrazone, or tri-p-tolylamine.

11. The photosensitive participate blend of claim 8, wherein the photosensitive build material is in the form of a free-flowing particulate suitable for use as a powder bed build material for 3-D printing.

12. A 3D printing system, comprising:
a photosensitive material set, including:
a build material comprising polymeric particles having an average size from 10 μm to 100 μm and an average aspect ratio of less than 2:1,
an inkjettable fluid suitable for application to the polymeric particles for 3D printing, and
a photosensitive dopant i) blended with the polymeric particles, ii) included in the inkjettable fluid or iii) both, wherein the photosensitive dopant has a first electrical property in a first chemical configuration and a second electrical property when modified to a second chemical configuration by exposure to photo electromagnetic radiation that is suitable to convert the photosensitive dopant from first chemical configuration to the second chemical configuration; and
a photo energy source for selectively emitting the photo electromagnetic radiation onto the build material either before or after the inkjettable fluid is applied to the build material.

13. The system of claim 12, wherein the inkjettable fluid is also a fusible ink suitable for fusing the build material when printed thereon.

14. The system of claim 12, wherein the photosensitive dopant is blended with the polymeric particles.

15. The system of claim 12, wherein the photo electromagnetic radiation is UV energy.
